(19) United States
(12) Patent Application Publication
(10) Pub. No.: US 2020/0045815 A1
(43) Pub. Date: Feb. 6, 2020

(54) CIRCUIT BOARD AND ELECTRONIC DEVICE INCLUDING THE SAME

(71) Applicant: CANON KABUSHIKI KAISHA, Tokyo (JP)

(72) Inventor: Takehiro Ito, Tokyo (JP)

(21) Appl. No.: 16/521,361

(22) Filed: Jul. 24, 2019

(30) Foreign Application Priority Data
Jul. 31, 2018 (JP) 2018-143937

(51) Int. Cl. H05K 1/02; H05K 5/04; H05K 1/18

(52) U.S. Cl. CPC H05K 1/0298; H05K 5/04; H05K 1/184; H05K 2201/0183; H05K 2201/2018; H05K 2201/093; H05K 2201/10409

(57) ABSTRACT

There is provided a circuit board including a laminated structure, a plurality of dielectric layers and a plurality of conductive layers. A connector and a circuit to which a signal is input via the connector are attached to a first conductive layer arranged on an outermost side of the circuit board. The first conductive layer includes a space between a first area in which the first conductive layer and an exterior of the connector are electrically connected and a second area in which the first conductive layer and the circuit are electrically connected, and at least one conductive layer different from the first conductive layer does not have a space between an area in which the at least one conductive layer is electrically connected to the first area and an area in which the at least one conductive layer is electrically connected to the second area.

### BACKGROUND OF THE INVENTION

### Field of the Invention

The present disclosure relates to a circuit board and an electronic device including the circuit board.

### Description of the Related Art

A circuit board having a laminated structure with a plurality of conductive layers and a plurality of dielectric layers is used in an electronic device. To the circuit board, an integrated circuit (IC) and a connector such as a universal serial bus (USB) connector and a local area network (LAN) connector are attached. The connector connects the electronic device to an external device. The connector to be attached to the circuit board has a metal exterior. The exterior of the connector and a conductive layer are connected by soldering, so that the connector is attached to the circuit board.

The connector, which connects the electronic device to the external device, is attached to the circuit board in such a manner that a port of the connector faces outward from the electronic device, so that the external device can be attached to the connector from outside the electronic device. Accordingly, static electricity may be applied to the exterior of the connector due to an external factor, for example, an event caused by a user touching the exterior of the connector. Exogenous noise such as static electricity generated in the exterior of the connector flows into a conductive layer of the circuit board via a joint portion between the exterior of the connector and the conductive layer. The exogenous noise that flows into the conductive layer can cause, for example, a malfunction of the IC attached to the circuit board.

In Japanese Patent Application Laid-Open No. 2014-36138, a space is provided, as illustrated in FIG. 1, between an area in which a metal casing of a connector is connected to a conductive layer and an area in which a circuit on a circuit board is connected to a conductive layer. In FIG. 1, a first layer 704, a second layer 706, a third layer 708, and a fourth layer 710 are conductive layers. The exterior of the connector is connected to the first layer 704 in an area 1001. The space arranged between the area 1001 in which the exterior of the connector is connected to the conductive layer and the area in which an IC 302 is connected to the conductive layer inhibits static electricity applied to the exterior of the connector from being transmitted to the IC 302 beyond the space.

In a device discussed in Japanese Patent Application Laid-Open No. 2014-36138, a space is provided, as illustrated in FIG. 1, between an area in which an exterior of a connector contacts a conductive layer and an area in which an IC on a circuit board contacts the conductive layer. Accordingly, a feedback current of an electric current that flows through a signal wire 502 flows along a route 503 indicated by a broken line. Thus, a current loop of the route 503 causes generation of radiation noise. Generally, the smaller the size of the current loop, the lower the level of the radiation noise.

### SUMMARY OF THE INVENTION

According to an aspect of the present disclosure, there is provided a circuit board including a laminated structure, a plurality of dielectric layers and a plurality of conductive layers. A connector having a conductive exterior and a circuit for processing a signal to be input via the connector are connected to a first conductive layer arranged on an outermost side of the plurality of conductive layers. The first conductive layer of the plurality of conductive layers includes a space between an area in which the first conductive layer and the exterior of the connector are electrically connected and an area in which the first conductive layer and the circuit are electrically connected, and at least one conductive layer different from the first conductive layer of the plurality of conductive layers does not have a space between an area in which the at least one conductive layer and the exterior of the connector are electrically connected and an area in which the at least one conductive layer and the circuit are electrically connected.

Further features of the present disclosure will become apparent from the following description of exemplary embodiments (with reference to the attached drawings).

### BRIEF DESCRIPTION OF THE DRAWINGS

FIG. 1 is a sectional view illustrating one example of a circuit board in a case where every conductive layer includes a slit between a frame ground and a signal ground.

FIG. 2 is a diagram illustrating a circuit board as seen from the top according to the present exemplary embodiment.

FIG. 3 is a sectional view along the line B-B′ on the circuit board illustrated in FIG. 2 according to the present exemplary embodiment.

FIG. 4 is a sectional view along the line A-A′ on the circuit board illustrated in FIG. 2 according to the present exemplary embodiment.

FIGS. 5A and 5B are diagrams each illustrating a shape of a connector according to the present exemplary embodiment.

FIG. 6 is a view illustrating a circuit board as seen from the top according to a second exemplary embodiment.

FIG. 7 is a sectional view along the line D-D′ on the circuit board illustrated in FIG. 6 according to the second exemplary embodiment.

### DESCRIPTION OF THE EMBODIMENTS

Hereinafter, exemplary embodiments are described with reference to the drawings.

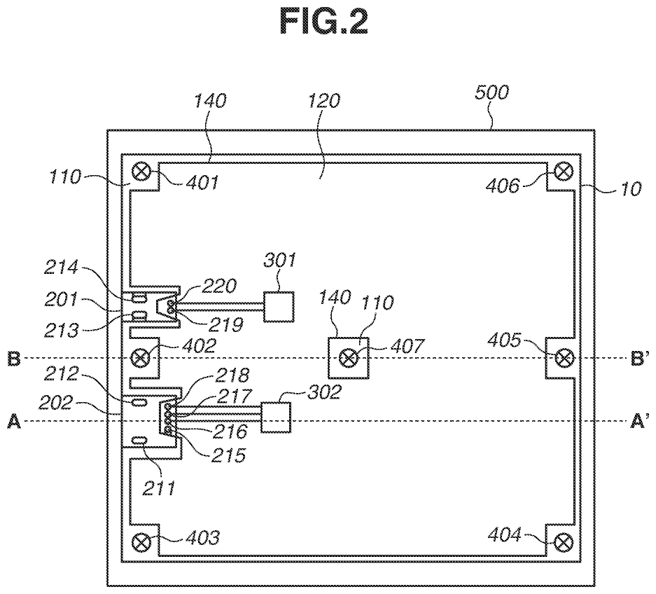

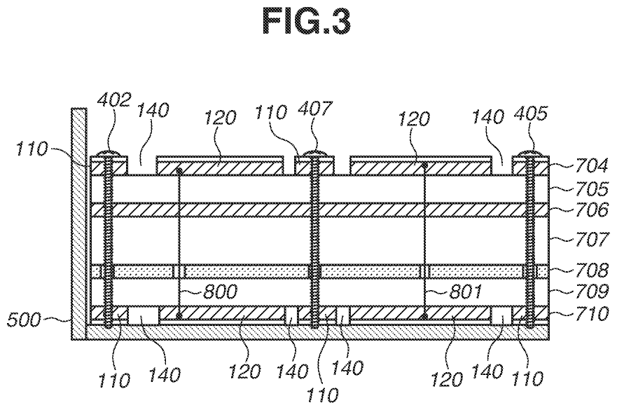

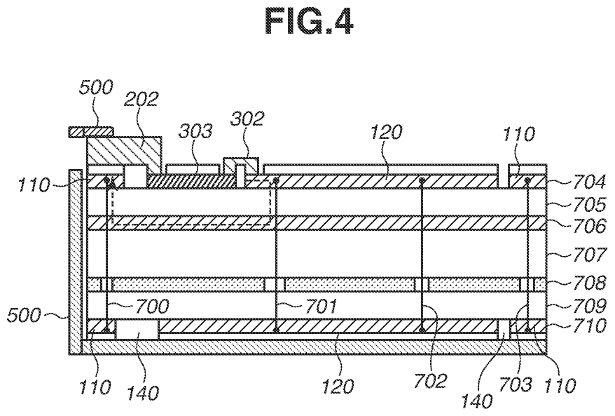

FIG. 2 is a top view of a circuit board 10 in a first exemplary embodiment. FIG. 3 is a sectional view along the line B-B′ on the circuit board 10 illustrated in FIG. 2, and FIG. 4 is a sectional view along the line A-A′ on the circuit board 10 illustrated in FIG. 2.

As illustrated in FIG. 3, the circuit board 10 of the present exemplary embodiment has a laminated structure in which four conductive layers and three dielectric layers are alternately arranged. In the present exemplary embodiment, a first layer 704, a second layer 706, a third layer 708, and a fourth layer 710 of the four conductive layers are arranged in order from a layer to which a connector is to be attached. A solder resist is deposited on the outermost conductive layer of the four conductive layers.

An overall configuration of the circuit board 10 is described with reference to FIG. 2. A sheet metal 500 is a metal plate to which the circuit board 10 is fixed with screws 401 through 407. The sheet metal 500 can be a metal housing of an electronic device. In the present exemplary embodiment, the sheet metal 500 is connected to a ground of a power supply.

The screws 401 through 407 are used to attach the circuit board 10 to the sheet metal 500. Each of the screws 401 through 407 is made of a conductive material. Therefore, in the conductive layers of the circuit board 10, portions in contact with the respective screws 401 through 407 are electrically connected to the sheet metal 500, and are at the same potential as the sheet metal 500.

Each of connectors 201 and 202 is a female connector surrounded by a metal exterior. Each of the connectors 201 and 202 is a general-purpose connector such as a local area network (LAN) connector, a universal serial bus (USB) connector, and a HDMI® connector, and inputs a signal that is input from an external device into the circuit board 10 to an integrated circuit (IC) attached to the circuit board 10. The connector 202 includes pins 211 and 212 that are ground terminals thereof. The connector 202 is connected to a conductive layer of the circuit board 10 via the pins 211 and 212. On the other hand, pins 215 through 217 of the connector 202 are terminals connected to an IC 302. Each of the pins 215 through 217 supplies a signal that is input from an external device via the connector 202 to the IC 302. Each of pins 213 and 214 of the connector 201 is a terminal that connects the connector 201 to the ground, and connects an exterior of the connector 201 to a conductive layer of the circuit board 10. On the other hand, each of pins 219 and 220 is a terminal that supplies a signal that is input from an external device or a cable via the connector 201 to an IC 301.

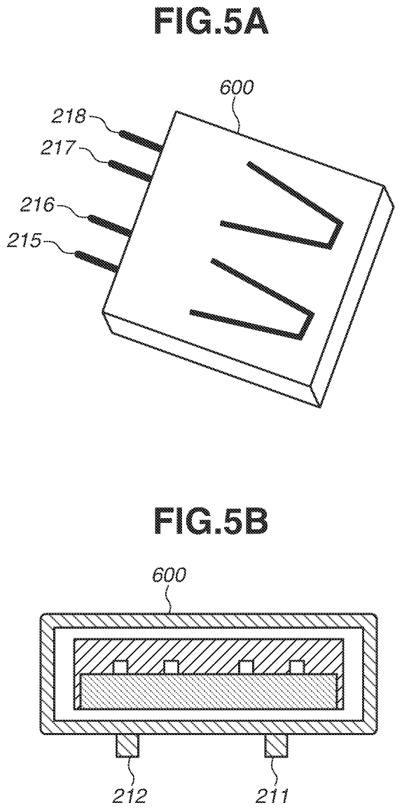

FIGS. 5A and 5B are diagrams each illustrating one example of appearance of the connector 202. FIG. 5A is a diagram of the connector 202 as seen from the top. As illustrated in FIG. 5A, the connector 202 has an exterior 600, which is a metal shell. Each of the pins 215 through 218 is to be connected to the first layer 704 of the circuit board 10, supplies a signal that is input to the connector 202 to the IC 302, and extends toward the side opposite a connecting portion of the connector 202. FIG. 5B is a diagram illustrating the connector 202 as seen from the side of the connecting portion of the connector 202. The pins 211 and 212 attach the connector 202 to the circuit board 10 to connect the exterior 600 of the connector 202 to the ground. The pins 211 and 212 are soldered to a pad arranged on the first layer 704 of the circuit board 10, so that the connector 202 is attached to the circuit board 10. The attachment of the pins 211 and 212 to the first layer 704 of the circuit board 10 electrically connects the exterior 600 of the connector 202 to the first layer 704 of the circuit board 10. As illustrated in FIG. 5B, a pin to be used for input of a signal is arranged inside the exterior 600. A user inserts a connector of an external device or a connector of a cable into the connector attached to the circuit board 10, so that the external device and the circuit board 10 are electrically connected. Each of the connectors 201 and 202 is arranged in a position to which the connector from outside the housing of the electronic device can be inserted. Further, a shape of each connector and the number of pins are not limited to the case described above.

Slits 140 are spaces that divide the first layer 704 and the fourth layer 710 of the circuit board 10 into an area 110 and an area 120 described below. In the circuit board 10, the area 110 includes a portion electrically connected to the sheet metal via any of the screws 401 through 407 and a portion in which an exterior of each of the connectors 201 and 202 contacts the first layer 704 of the circuit board 10. In other words, the area 110 is a frame ground area electrically connected to an exterior of the connector. The pins 213 and 214 of the connector 201 connect an exterior of the connector 201 to the first layer 704 of the circuit board 10. The pins are arranged in the area 110. The pins 211 and 212 of the connector 202 connect the exterior of the connector 202 to the first layer 704 of the circuit board 10. The pins are arranged in the area 110.

Since static electricity generated in the exterior of the connector 201 or 202 does not go over the slit 140, the static electricity flows into any of the screws 401 through 405 via a layer nearest to a surface layer of the conductive layers of the circuit board 10. The static electricity generated in the exterior of the connector 201 or 202 flows into a ground wire of the power supply from the screws 401 through 405 via the sheet metal 500. Accordingly, owing to the slit 140, static electricity generated in an exterior of the connector 201 or 202 does not flow into the IC 301 or 302. Thus, a malfunction of each of the ICs 301 and 302 due to the static electricity generated outside the electronic device is prevented.

In the circuit board 10, the area 120 differs from the area 110. The area 120 is a signal ground area in which ground terminals of the ICs 301 and 302 are connected to the circuit board 10. The ground terminals of the ICs 301 and 302 are in contact with the area 120, and a reference potential of each of the ICs 301 and 302 is the same as a potential of a ground layer of the circuit board 10. The pins 219 and 220 of the connector 201 are connected to the IC 301, and are arranged in the area 120. The pins 215 through 218 of the connector 202 are connected to the IC 302, and are arranged in the area 120.

A configuration of the circuit board 10 and a method for attaching the circuit board 10 to the sheet metal 500 are described with reference to FIG. 3.

The circuit board 10 is a circuit board on which dielectric layers (i.e., prepregs 705 and 709 and a core member 707) and conductive layers 704, 706, 708, and 710 are alternately laminated. Each of the prepregs 705 and 709 and the core member 709 is made of an insulation material, and used to insulate the conductive layers 704, 706, 708, and 710 from each other.

Each of the conductive layers 704, 706, 708, and 710 is formed with copper foil. The first layer 704 (i.e., the conductive layer 704) and the fourth layer 710 (i.e., the conductive layer 710), both of which are conductive layers, are signal layers to be used for, for example, input of signals to an IC. On the first layer 704 and the fourth layer 710, pads and through holes are formed to attach the connectors 201 and 202 and the ICs 301 and 302 in addition to a signal wire. On the first layer 704 and the fourth layer 710, a portion other than the pad or the through hole is coated with a solder resist. The pad is a portion on which a device or the like is to be attached. The solder resist prevents oxidation of the copper foils of the first layer 704 and the fourth layer 710 and adhesion of solder to the portion other than the pad.

The second layer 706 (i.e., the conductive layer 706) is a ground (GND) layer, and is a layer to have a reference potential with respect to a signal that is input to each of the ICs 301 and 302 arranged on the circuit board 10. On the GND layer, a wiring pattern is formed to cause a feedback current of an electric current flowing through a signal wire to flow through the wiring pattern. The third layer 708 (i.e., the conductive layer 708) is a power layer on which a wiring pattern is formed to supply electric power to the ICs 301 and 302 arranged on the circuit board 10.

The circuit board 10 is attached to the sheet metal 500 with screws 402, 405, and 407. Each of the screws is made of a conductive material, and contacts an area 110 of the first layer 704, the second layer 706, and an area 110 of the fourth layer 710. Specifically, the area 110 of the first layer 704, the second layer 706, and the area 110 of the fourth layer 710 are electrically connected via the screws 402, 405, and 407, and are at the same potential as the sheet metal 500. The screws 401, 403, 404, and 406, which are not illustrated in FIG. 3, also contact the area 110 of the first layer 704, the second layer 706, and the area 110 of the fourth layer 710, and are at the same potential as the sheet metal 500.

Vias 800 and 801 are portions that cause the first layer 704, the second layer 706, and the fourth layer 710 to be electrically conductive. A via represents a through hole that is not used for insertion of a component of through holes, the inner sides of which are plated with copper for connection of the plurality of conductive layers. An area 120 of the first layer 704, the second layer 706, and an area 120 of the fourth layer 710 are electrically connected via the vias 800 and 801. A via is appropriately arranged in a position other than the positions of the vias 800 and 801 to electrically connect layers other than the third layer 708 as a power layer. The layers include the first layer 704, the second layer 706, and the fourth layer 710.

The slits 140 are spaces that separate the first layer 704 and the fourth layer 710 of the circuit board 10 into the area 110 and the area 120. As illustrated in a sectional view of FIG. 3, the slits 140 are formed to separate the first layer 704 and the fourth layer 710 of the circuit board 10 into the area 110 and the area 120. The second layer 706 is not separated by the slits 140. Accordingly, the second layer 706 of the circuit board 10 is electrically connected regardless of position.

Moreover, in the present exemplary embodiment, a slit 140 is arranged near the screw 407 in the center of the circuit board 10. As illustrated in the sectional view of FIG. 3, slits 140 are arranged around the screw 407 in the first layer 704 and the fourth layer 710, whereas a slit 140 is not arranged around the screw 407 in the second layer 706. An area 110 of the first layer 704, an area 110 of the fourth layer 710, the second layer 706, and the sheet metal 500 are electrically connected by the screw 407. Accordingly, if noise such as static electricity has been applied to the sheet metal 500, the noise is applied to the first layer 704 or the fourth layer 710 via the screw 407. Therefore, arrangement of the slit 140 around the screw 407 can prevent noise such as static electricity from being applied to the area 120, which has a signal wire, of the first layer 704 and the fourth layer 710.

FIG. 4 illustrates a sectional view along the line A-A′ on the circuit board 10 illustrated in FIG. 2. The A-A′ sectional view includes a signal wire of the connector 202.

Similar to a USB connector and a LAN connector, the connector 202 connects the electronic device to another device. A user inserts a connector of a device or a cable having a shape that fits the connector 202 into the connector 202, thereby connecting the electronic device to the external device. The connector 202 receives an input signal from the connected device or the cable. The input signal is input to the IC 302 via a signal wire 303. An electric current that flows into a ground terminal of the IC 302 flows to the first layer 704 of the circuit board 10 via a joint portion of the ground terminal. The electric current that has flowed into the first layer 704 of the circuit board 10 flows into the second layer 706 via a via 701. The electric current that has flowed into the second layer 706 flows along a direction indicated by an arrow illustrated in FIG. 4 inside the second layer 706, and then flows to the first layer 704 of the circuit board 10 via a via 700. Subsequently, the electric current having flowed to the first layer 704 flows into the connector 202 from either the ground terminal 212 or 211 of the connector 202.

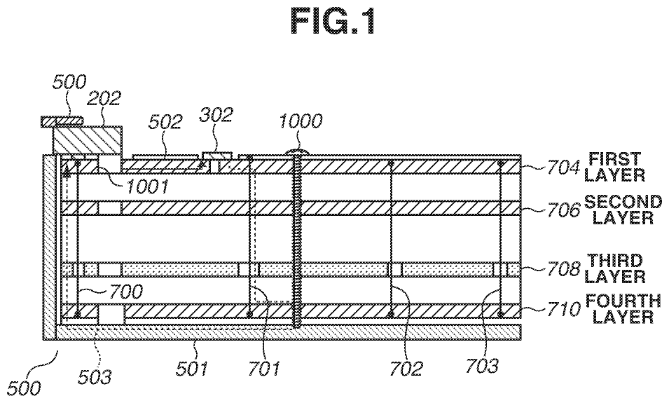

In the present exemplary embodiment, a slit is not arranged in the second layer 706, which is different from the outermost layer, of the conductive layers of the circuit board 10. Accordingly, a feedback circuit through which the electric current that has flowed into the ground of the IC 302 returns to the connector can be provided in the area 110 of the circuit board 10 via the second layer 706. Accordingly, a route through which a feedback current flows can be shorter than the route of a case where a slit is provided between a frame ground and a signal ground in every layer. Further, the feedback current flows through the second layer 706 and then returns to the connector 202, so that a signal to be output via a signal wire of the connector and a feedback current loop of such a signal can be smaller than those illustrated in FIG. 1. Therefore, radiation noise generated by the signal wire 303 and the feedback current can be lower than a case where a slit is arranged between a frame ground and a signal ground in every layer.

As described above, in a circuit board having a laminated structure with conductive layers and dielectric layers, a first layer, which is an outermost layer of the conductive layers, has a slit between an area in which the conductive layer contacts an exterior of a connector and an area in which the conductive layer is connected to a pin of a ground of an IC. Thus, even if static electricity is generated due to touching of metal such as an exterior of the connector by a user, the static electricity can be prevented from being transmitted via the first layer of the circuit board to the IC. Moreover, the aforementioned slit is not provided in a layer different from the first layer, which is the outermost layer of the conductive layers. Accordingly, a route for a feedback current of a signal that has flowed to the circuit board can be shortened, and radiation noise generable by the signal and the feedback current can be reduced.

In the first exemplary embodiment, an example has been described in which pins for connecting exteriors of the connectors 201 and 202 to the ground contact only the first layer 704 of the circuit board 10. Terminals for connecting the exteriors of the connectors 201 and 202 to a frame ground may contact not only the first layer 704 but also the fourth layer 710 arranged below the ground layer. Herein, terminals of the connectors 201 and 202 that are to be connected to the ground may contact the second layer 706 as a ground layer. In such a case, if noise is generated in the exterior of the connector, the noise is provided on the second layer 706 as the ground layer. Therefore, in a second exemplary embodiment, a slit is provided in a portion in which a terminal of a connector that is connected to the ground is arranged within a second layer 706 as a ground layer in such a manner that the second layer 706 does not contact a pin of the connector. Meanwhile, in a portion in which a pin of the connector that is connected to the ground is not arranged, a slit is not provided in the ground layer in such a manner that a feedback current can flow into an area 110.

With such arrangement, even if a plurality of signal layers across a ground layer is connected to a ground terminal connected to an exterior of the connector, generation of radiation noise due to a feedback current of a signal is inhibited while suppressing exogenous noise from being present on a ground layer of a circuit board.

Materials and a layer structure of a circuit board 10 of the second exemplary embodiment are similar to those of the first exemplary embodiment.

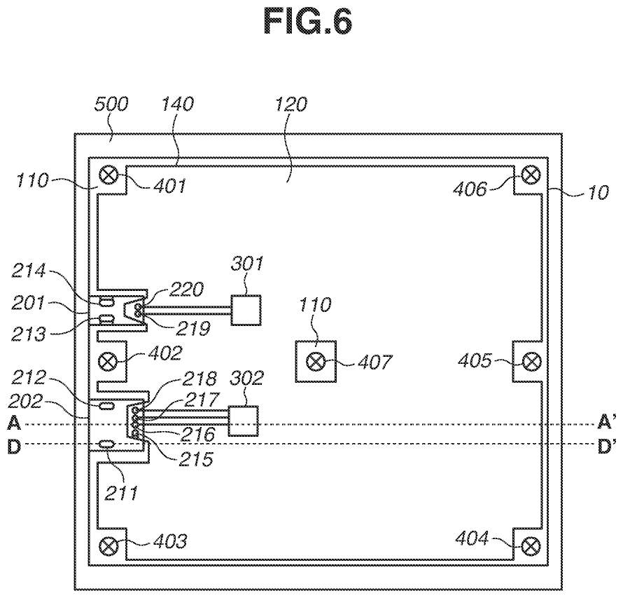

FIG. 6 is a diagram of the circuit board 10 as seen from the top. In the second exemplary embodiment, a sectional view along the line D-D′ on FIG. 6. will be discussed. The D-D′ sectional view is a plane including a pin 211 that is connected to the ground of pins of a connector 202.

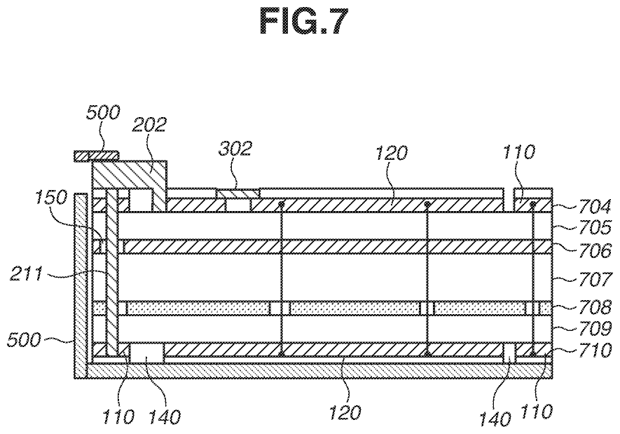

FIG. 7 is a sectional view along the line D-D′ on the circuit board 10 illustrated in FIG. 6. The pin 211 connects an exterior of the connector 202 to a first layer 704 and a fourth layer 710 of the circuit board 10. In each of the first layer 704 and the fourth layer 710, an area in contact with the pin 211 is at the same potential as a sheet metal 500 via a member such as a screw, and is a frame ground area, the reference potential of which is the sheet metal 500. If noise is generated in the exterior of the connector 202, the noise passes through the fourth layer 710 of the circuit board 10 via the pin 211, and then flows to the sheet metal 500 from any of screws 401 through 407 that are not illustrated in FIG. 7. In the present exemplary embodiment, an impedance of the pin 211 is lower than that of any of the screws 401 through 406, and noise such as static electricity flows into the pin 211.

On the other hand, a sectional view along the line A-A′ of FIG. 6 does not have a pin 211 for connecting a metal shell of the connector to the first layer 704 of the circuit board 10, and thus is similar to the sectional view illustrated in FIG. 4 of the first exemplary embodiment. In FIG. 4, a frame ground and a signal ground of the second layer 706 of the circuit board 10 contact each other, and a slit is not provided. Therefore, even if a pin for connecting an exterior of a connector to the ground contacts a plurality of layers across a ground layer of the circuit board 10, radiation noise due to a feedback circuit of a signal can be inhibited.

In the second exemplary embodiment as described above, in a case where a ground terminal, which is to be connected to an exterior of a connector, is connected to a plurality of signal layers of a circuit board, a slit is provided in a ground layer of the circuit board such that the ground terminal and copper foil of the ground layer of the circuit board do not contact each other. Further, the ground layer is connected to a frame ground in an area other the portion having the ground terminal. Such arrangement can shorten a route for a feedback current of a signal flowing through a signal layer of the circuit board.

In the second exemplary embodiment, as described above, a space is provided between an area, the reference potential of which is a sheet metal and an area, the reference potential of which is a ground layer in a signal layer of the circuit board. Thus, noise such as static electricity generated in an exterior of the connector is inhibited from flowing into an IC inside the circuit and a ground layer of the circuit board. Moreover, a space is provided around a ground terminal in such a manner that the ground layer does not contact the ground terminal. Thus, the provided space can inhibit radiation noise generated by a signal flowing to an IC and a feedback current of such a signal.

Each of the exemplary embodiments have been described using a circuit board having four conductive layers and three dielectric layers that are alternately deposited. However, the number of conductive layers and the number of dielectric layers are not limited thereto as long as conductive layers and dielectric layers are alternately deposited.

The circuit board according to each of the exemplary embodiments can inhibit generation of noise due to an electric current flowing through a signal wire on the circuit board and a feedback current of the electric current, while inhibiting propagation of influence of noise to be applied from an external unit to a circuit on the circuit board.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2018-143937, filed Jul. 31, 2018, which is hereby incorporated by reference herein in its entirety.

What is claimed is:

1. A circuit board comprising:
a laminated structure;
a plurality of dielectric layers; and
a plurality of conductive layers,
wherein, the circuit board includes a connector and a circuit to which a signal is input via the connector that is attached to a first conductive layer arranged on an outermost side of the plurality of conductive layers,
wherein, in the first conductive layer of the plurality of conductive layers, a first area to which an exterior of the connector is to be attached is separated from a second area to which the circuit is to be attached, and
wherein, in at least one conductive layer different from the first conductive layer of the plurality of conductive layers, an area to be electrically connected to the first area is not separated from the second area.

2. The circuit board according to claim 1,
wherein the circuit board is attached to a metal housing of an electronic device by a screw, and
wherein the first area contacts the screw.

3. The circuit board according to claim 2, wherein the second area does not contact the screw by which the circuit board is attached to the metal housing of the electronic device.

4. The circuit board according to claim 1, wherein the second area of the first conductive layer is connected to a terminal to which a signal from the connector is input.

5. The circuit board according to claim 1,
wherein the first conductive layer is a layer in which a signal wire for input of a signal from the connector to the circuit is to be arranged, and
wherein the at least one conductive layer different from the first conductive layer is a ground layer.

6. The circuit board according to claim 5, wherein the ground layer is a conductive layer nearest to the first conductive layer of the plurality of conductive layers.

7. The circuit board according to claim 6, wherein the ground layer is electrically connected to a metal housing of an electronic device.

8. The circuit board according to claim 7, wherein the first conductive layer of the circuit board and the ground layer are electrically connected through a via.

9. The circuit board according to claim 5, wherein one of the plurality of conductive layers is a power layer, and the power layer supplies an electric current to the circuit.

10. The circuit board according to claim 9, wherein the ground layer and the power layer are not electrically connected.

11. The circuit board according to claim 1, wherein the first area is an area including an end portion of the circuit board.

12. The circuit board according to claim 1, wherein the first area is a frame ground, and the second area is a signal ground.

13. The circuit board according to claim 2, wherein the metal housing of the electronic device is grounded.

14. The circuit board according to claim 1, wherein the connector is a universal serial bus connector or a local area network connector.

15. The circuit board according to claim 1, wherein the circuit board has a space between the first area and the second area in each of a plurality of signal layers of the plurality of conductive layers.

16. A circuit board having a laminated structure with a plurality of dielectric layers and a plurality of conductive layers, the circuit board comprising:
a first conductive layer having a space between a first area to which an exterior of a conductive connector is electrically connected and a second area to which a circuit to which a signal is input via the connector is electrically connected; and
at least one conductive layer having no space between an area to be electrically connected to the first area and an area to be electrically connected to the second area.

17. An electronic device comprising:
a circuit board including,
a laminated structure;
a plurality of dielectric layers; and
a plurality of conductive layers,
wherein, the circuit board includes a connector and a circuit to which a signal is input via the connector that is attached to a first conductive layer arranged on an outermost side of the plurality of conductive layers,
wherein, in the first conductive layer of the plurality of conductive layers, a first area to which an exterior of the connector is to be attached is separated from a second area to which the circuit is to be attached, and
wherein, in at least one conductive layer different from the first conductive layer of the plurality of conductive layers, an area to be electrically connected to the first area is not separated from the second area.
